(19) United States
(12) Patent Application Publication
(10) Pub. No.: US 2014/0055175 A1
(43) Pub. Date: Feb. 27, 2014

(54) High-Voltage Driver Integratable with an Integrated Circuit

(71) Applicant: LUXUL TECHNOLOGY INCORPORATION, New Taipei City (TW)

(72) Inventors: Cheng-Hung Pan, New Taipei City (TW); Perng-Fei Yuh, New Taipei City (TW)

(73) Assignee: LUXUL TECHNOLOGY INCORPORATION, New Taipei City (TW)

(21) Appl. No.: 13/970,709

(22) Filed: Aug. 20, 2013

(30) Foreign Application Priority Data
Aug. 27, 2012 (TW) 101130944

(51) Int. Cl. H03K 17/082

(52) U.S. Cl. CPC H03K 17/0822
USPC 327/109

(57) ABSTRACT

A high-voltage driver integratable with an integrated circuit has a switching transistor, a switching diode, a first resistor, a second resistor, and a control transistor. The anode of the switching diode is connected to the source of the switching transistor. The cathode of the switching diode is connected to the gate of the switching transistor. When the source voltage of the switching transistor is far greater than the cut-in voltage of the switching diode, the switching diode is forward-biased, and the gate-source voltage of the switching transistor is equal to the negative cut-in voltage. Accordingly, high voltage will not be generated across the gate-source junction of the switching transistor, no junction breakdown will occur between the gate and source thereof, and the high-voltage driver can be integrated with an integrated circuit.

### BACKGROUND OF THE INVENTION

1. Field of the Invention

The present invention relates to a high-voltage switch, and more particularly to a high-voltage driver integratable with an integrated circuit.

2. Description of the Related Art

The widespread applications of metal oxide semiconductor field effect transistor (MOSFET) are attributable to the saturation of the semiconductor fabrication techniques. However, as a switch, MOSFET has the weakness of being inapplicable under a high-voltage environment.

With reference to FIG. 5, the weakness resides in that when users connect the gate 31 of the MOSFET 30 to the ground and the MOSFET enters the cutoff region between the drain 32 and the source 33, a junction breakdown occurs between the gate 31 and the source 33. Instead of MOSFET, relays are commonly used in the market as high-voltage switches.

With reference to FIG. 6, a conventional relay 40 is an electronically controlled element, and has a core 41, a coil 42, an armature 43, and two leaf spring contacts 44. When a constant voltage V_{dc} is applied to two ends of the coil 42, the coil 42 generates an electromagnetic effect attracting the armature 43 to the core 41 and driving the leaf spring contacts 44 to be attracted to each other. When the coil 42 is powered off, the electromagnetic attraction is unavailable, the armature 43 returns to its original position, and the two leaf spring contacts are separated. By toggling between the contacting and separating states of the leaf spring contacts, the relay 40 connects and disconnects a circuit. As a result, the conventional relays play critical roles in circuit conversion, safety protection and signal isolation.

As having better signal isolating effect, the conventional relays are usually operated as a type of high-voltage switches. By applying a relatively low constant voltage V_{dc} to both ends of the coil 42, the two leaf spring contacts 44 serially connected to two relatively high voltages can be controlled to power on or off a circuit loop connected with the leaf spring contacts 44.

However, as the conventional relay 40 fails to be integrated to large-scale circuits because it is too bulky relative to large-scale circuits, the conventional relay 40 is difficult to be applied to compact and high voltage electronic products. Furthermore, although the MOSFET 30 itself can be integrated to large-scale circuits, the junction breakdown occurring between the gate 31 and the source 33 as a result of high voltage operation renders the MOSFET 30 infeasible as a high-voltage solution.

### SUMMARY OF THE INVENTION

An objective of the present invention is to provide a high-voltage driver integratable with an integrated circuit.

To achieve the foregoing objective, the high-voltage driver integratable with an integrated circuit has a switching transistor, a switching diode, a first resistor, a second resistor, and a control transistor.

The switching transistor has a drain, a source, and a gate.

The switching diode has an anode and a cathode. The anode is connected to the source of the switching transistor. The cathode is connected to the gate of the switching transistor.

The first resistor has a first end and a second end. The first end is connected to the gate of the switching transistor.

The second resistor has a first end and a second end. The first end is connected to the drain of the switching transistor. The second end is connected to the second end of the first resistor.

The control transistor has a drain, a source, and a gate. The drain is connected to the second resistor and the second end of the first resistor. The source is connected to the ground.

To achieve the foregoing objective, the high-voltage driver integratable with an integrated circuit alternatively has a switching diode, a boost capacitor, a first resistor, a second resistor, a first control transistor, and a second control transistor.

The switching transistor has a drain, a source, and a gate.

The switching diode has an anode and a cathode. The anode is connected to the source of the switching transistor. The cathode is connected to the gate of the switching transistor.

The boost capacitor has a first end and a second end. The first end is connected to the gate of the switching transistor.

The first resistor has a first end and a second end. The first end is connected to the gate of the switching transistor.

The second resistor has a first end and a second end. The first end is connected to the drain of the switching transistor. The second end is connected to the second end of the first resistor.

The first control transistor has a drain, a source, and a gate. The drain is connected to the second end of the first resistor. The source is connected to the ground.

The second control transistor has a drain, a source, and a gate. The drain is connected to the second end of the boost capacitor. The source is connected to the ground. The gate is connected to the gate of the first control transistor.

Given the foregoing high-voltage driver, when the source voltage of the switching transistor is far greater than the gate voltage thereof and is greater than the cut-in voltage of the switching diode, the switching diode is forward-biased. The gate-source voltage of the switching transistor is thus equal to the negative cut-in voltage of the switching diode such that high voltage will not be generated across the junction between the gate and the source of the switching transistor and the junction breakdown will not occur between the gate and the source of the switching transistor. Accordingly, the high-voltage driver can be integrated to an integrated circuit.

Other objectives, advantages and novel features of the invention will become more apparent from the following detailed description when taken in conjunction with the accompanying drawings.

### BRIEF DESCRIPTION OF THE DRAWINGS

FIG. 1 is a circuit diagram of a first embodiment of a high-voltage driver integratable with an integrated circuit in accordance with the present invention;

FIG. 2 is associated with waveform diagrams of signals of a switching transistor and a control transistor of the high-voltage driver in FIG. 1;

FIG. 3 is a circuit diagram of a second embodiment of a high-voltage driver integratable with an integrated circuit in accordance with the present invention;

FIG. 4 is associated with waveform diagrams of signals of a switching transistor and two control transistors of the high-voltage driver in FIG. 3;

FIG. 5 is a structural diagram of a conventional MOSFET; and

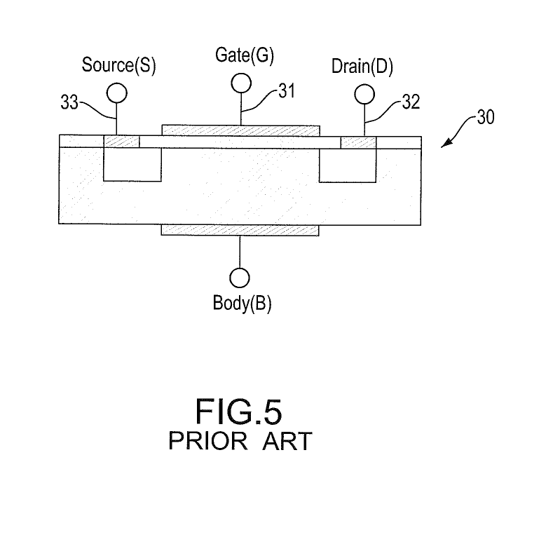

FIG. 6 is a circuit diagram of a conventional relay.

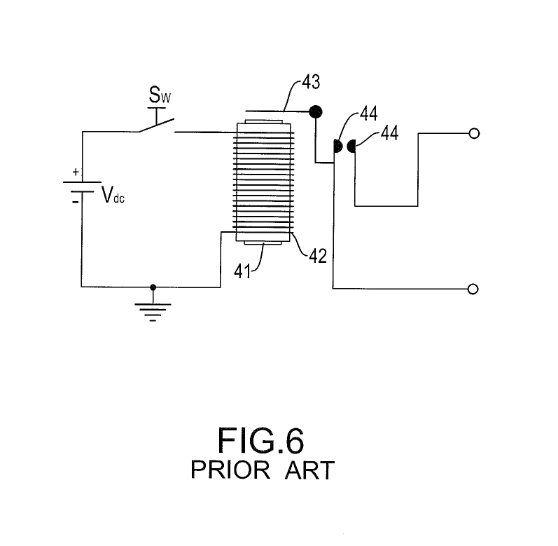

### DETAILED DESCRIPTION OF THE INVENTION

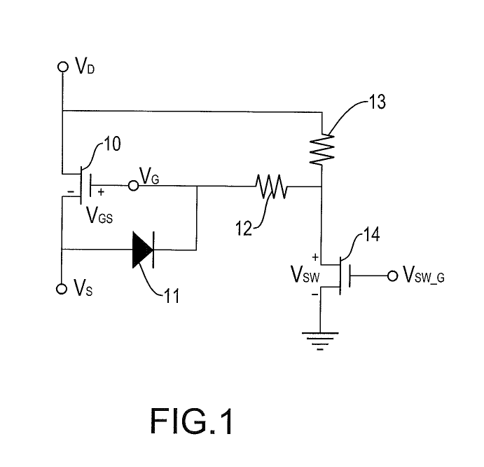

With reference to FIG. 1, a first embodiment of a high-voltage driver integratable with an integrated circuit in accordance with the present invention has a switching transistor 10, a switching diode 11, a first resistor 12, a second resistor 13, and a control transistor 14.

The switching transistor 10 has a drain, a source and a gate. In the present embodiment, the switching transistor 10 is a MOSFET or a bipolar junction transistor (BJT).

The switching diode 11 has an anode and a cathode. The anode is connected to the source of the switching transistor 10. The cathode is connected to the gate of the switching transistor 10.

The first resistor 12 has a first end and a second end. The first end of the first resistor 12 is connected to the gate of the switching transistor 10.

The second resistor 13 has a first end and a second end. The first end of the second resistor 13 is connected to the drain of the switching transistor 10. The second end of the second resistor 13 is connected to the second end of the first resistor 12.

The control transistor 14 has a drain, a source, and a gate. The drain of the control transistor 14 is connected to the second resistor 13 and the second end of the first resistor 12. The source of the control transistor 14 is connected to the ground. In the present embodiment, the control transistor 14 is a MOSFET or a BJT.

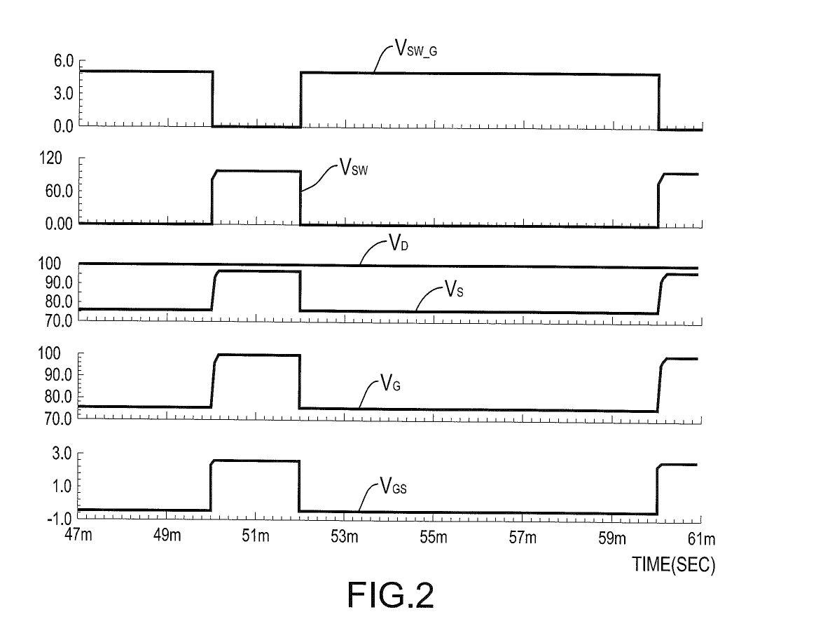

With reference to FIG. 2, a drain voltage V_{D} and a source voltage V_{S} of the switching transistor 10 are respectively set to be 100 V and 80 V. When a gate voltage V_{SW}_{_{—}}_{G} of the control transistor 14 is 6 V, the cathode of the switching diode 11 is connected to the ground through the first resistor 12. As the switching diode 11 is forward-biased at the moment, the gate-source voltage V_{GS} of the switching transistor 10 is equal to a negative value of a cut-in voltage (−0.7 V) of the switching diode 10 such that the switching transistor 10 turns off. When the gate voltage V_{SW}_{_{—}}_{G} of the control transistor 14 is 0 V, the cathode of the switching diode 11 is connected to the drain of the switching transistor 10 through the first resistor 12 and the second resistor 13. As the switching diode 11 is reverse-biased at the moment, the first resistor 12, the second resistor 13, and the switching transistor 10 constitute a negative feedback loop from the drain of the switching transistor 10 to the gate of the switching transistor 10. Hence, a gate voltage V_{G} of the switching transistor 10 is equal to the drain voltage V_{D} such that the switching transistor 10 turns on. Accordingly, the input voltage 100 V can be disconnected and switched off by the high-voltage driver to perform a switch-off function at high voltage.

A state of MOSFET entering the saturation region can be determined by the following equation.

I_{D}=μₙCₒₓW/2L(V_{GS}−Vₜₕ)²

The switching transistor 10 can enter the saturation region only if a drain-source voltage V_{DS} thereof is less than a difference value between the gate-source voltage V_{GS} and a pinch-off (threshold) voltage Vₜₕ. Therefore, the gate-source voltage V_{GS} should be greater than a sum of the drain-source voltage V_{DS} and the pinch-off voltage Vₜₕ.

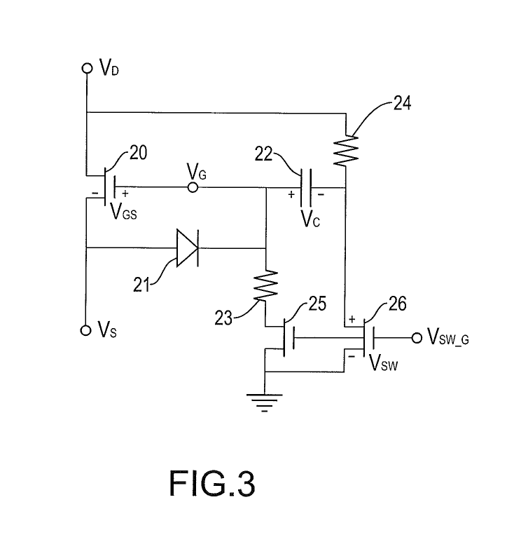

With reference to FIG. 3, a second embodiment of a high-voltage driver integratable with an integrated circuit in accordance with the present invention has a switching transistor 20, a switching diode 21, a boost capacitor 22, a first resistor 23, a second resistor 24, a first control transistor 25, and a second control transistor 26.

The switching transistor 20 has a drain, a source, and a gate. In the present embodiment, the switching transistor 20 is a MOSFET or a BJT.

The switching diode 21 has an anode and a cathode. The anode of the switching diode 21 is connected to the source of the switching transistor 20. The cathode of the switching diode 21 is connected to the gate of the switching transistor 20.

The boost capacitor 22 has a first end and a second end. The first end of the boost capacitor 22 is connected to the gate of the switching transistor 20.

The first resistor 23 has a first end and a second end. The first end of the first resistor 23 is connected to the gate of the switching transistor 20.

The second resistor 24 has a first end and a second end. The first end of the second resistor 24 is connected to the drain of the switching transistor 20. The second end of the second resistor 24 is connected to the second end of the boost capacitor 22.

The first control transistor 25 has a drain, a source, and a gate. The drain of the first control transistor 25 is connected to the second end of the first resistor 23. The source of the first control transistor 25 is connected to the ground. In the present embodiment, the first control transistor 25 is a MOSFET or a BJT.

The second control transistor 26 has a drain, a source, and a gate. The drain of the second control transistor 26 is connected to the second end of the boost capacitor 22. The source of the second control transistor 26 is connected to the ground. The gate of the second control transistor 26 is connected to the gate of the first control transistor 25. In the present embodiment, the second control transistor 26 is a MOSFET or a BJT.

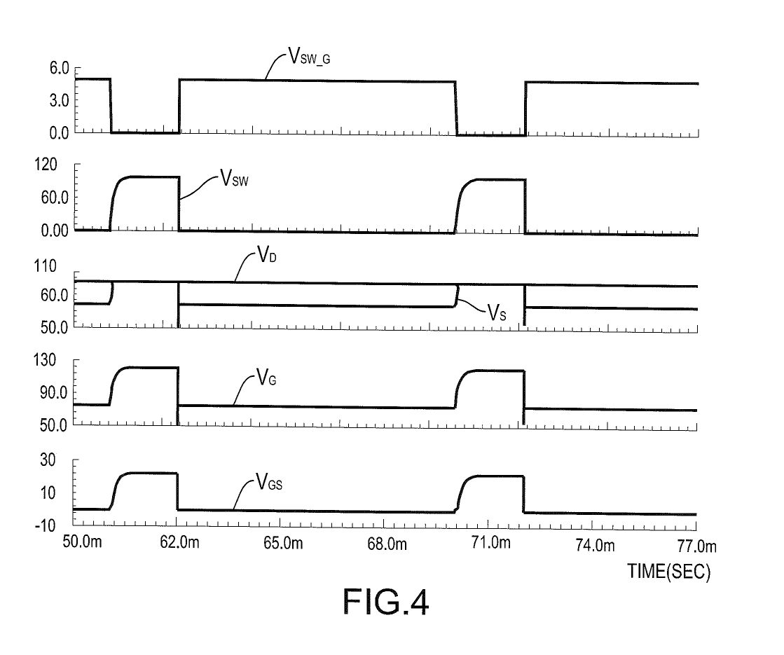

With reference to FIG. 4, a drain voltage V_{D} and a source voltage V_{S} of the switching transistor 20 are respectively set to be 100 V and 80 V. When a gate voltage V_{SW}_{_{—}}_{G} of each of the first control transistor 25 and the second control transistor 26 is 6 V, the switching diode 21 is forward-biased such that the switching transistor 20 turns off and the boost capacitor 22 is charged. When the gate voltage V_{SW}_{_{—}}_{G} of each of the first control transistor 25 and the second control transistor 26 is 0 V, the second resistor 24, the boost capacitor 22, and the switching transistor 20 constitute a negative feedback loop from the drain of the switching transistor 20 to the gate of the switching transistor 20. As the first end and the second end of the boost capacitor 22 both have a charged voltage V_{C}, the gate voltage V_{G} of the switching transistor 20 is equal to a sum of the drain voltage V_{D} thereof and the charged voltage V_{C} such that the switching transistor 20 turns on and enters the saturation region. Accordingly, the input voltage 100 V can be disconnected or short-connected by the high-voltage driver to perform a switch-off function at high voltage.

In sum, given the high-voltage driver of the present invention with the gate and the source of the switching transistor 10, 20 connected to the switching diode 11, 21, the gate of the switching transistor 10, 20 is connected to the ground. When the source voltage V_{S} of the switching transistor 10, 20 is far greater than the gate voltage V_{G} thereof and is greater than the cut-in voltage of the switching diode 11, 21, the switching diode 11, 21 is forward-biased. The gate-source voltage of the switching transistor 10, 20 is equal to the negative cut-in voltage (−0.7 V) of the switching diode 11, 21 such that high voltage will not be generated across the junction between the gate and the source of the switching transistor 10, 20 and the junction breakdown will not occur between the gate and the source of the switching transistor 10, 20. Accordingly, the high-voltage driver can be integrated to an integrated circuit.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A high-voltage driver integratable with an integrated circuit, comprising:
a switching transistor having a drain, a source, and a gate;
a switching diode having:
an anode connected to the source of the switching transistor; and
a cathode connected to the gate of the switching transistor;
a first resistor having:
a first end connected to the gate of the switching transistor; and
a second end;
a second resistor having:
a first end connected to the drain of the switching transistor; and
a second end connected to the second end of the first resistor; and
a control transistor having:
a drain connected to the second resistor and the second end of the first resistor;
a source connected to the ground; and
a gate.

2. The high-voltage driver as claimed in claim 1, wherein the switching transistor is a metal oxide semiconductor field effect transistor (MOSFET) or a bipolar junction transistor (BJT).

3. The high-voltage driver as claimed in claim 1, wherein the control transistor is a MOSFET or a BJT.

4. The high-voltage driver as claimed in claim 2, wherein the control transistor is a MOSFET or a BJT.

5. A high-voltage driver integratable with an integrated circuit, comprising:
a switching transistor having a drain, a source, and a gate;
a switching diode having:
an anode connected to the source of the switching transistor; and
a cathode connected to the gate of the switching transistor;
a boost capacitor having:
a first end connected to the gate of the switching transistor; and
a second end;
a first resistor having:
a first end connected to the gate of the switching transistor; and
a second end;
a second resistor having:
a first end connected to the drain of the switching transistor; and
a second end connected to the second end of the boost capacitor; and
a first control transistor having:
a drain connected to the second end of the first resistor;
a source connected to the ground; and
a gate; and
a second control transistor having:
a drain connected to the second end of the boost capacitor;
a source connected to the ground; and
a gate connected to the gate of the first control transistor;

6. The high-voltage driver as claimed in claim 5, wherein the switching transistor is a MOSFET or a BJT.

7. The high-voltage driver as claimed in claim 5, wherein the first control transistor is a MOSFET or a BJT.

8. The high-voltage driver as claimed in claim 6, wherein the first control transistor is a MOSFET or a BJT.

9. The high-voltage driver as claimed in claim 5, wherein the second control transistor is a MOSFET or a BJT.

10. The high-voltage driver as claimed in claim 6, wherein the second control transistor is a MOSFET or a BJT.

11. The high-voltage driver as claimed in claim 7, wherein the second control transistor is a MOSFET or a BJT.

12. The high-voltage driver as claimed in claim 8, wherein the second control transistor is a MOSFET or a BJT.
